(19) United States
(12) Patent Application Publication
(10) Pub. No.: US 2014/0151770 A1
(43) Pub. Date: Jun. 5, 2014

(54) THIN FILM DEPOSITION AND LOGIC DEVICE

(71) Applicant: INTERNATIONAL BUSINESS MACHINES CORPORATION, Armonk, NY (US)

(72) Inventors: Ching-Tzu Chen, Ossining, NY (US); Marcin J. Gajek, Yorktown Heights, NY (US); Simone Raoux, New York, NY (US)

(73) Assignee: INTERNATIONAL BUSINESS MACHINES CORPORATION, Armonk, NY (US)

(21) Appl. No.: 13/689,857

(22) Filed: Nov. 30, 2012

(51) Int. Cl. H01L 29/82; H01L 43/12

(52) U.S. Cl. CPC H01L 29/82; H01L 43/12; B82Y 40/00
USPC 257/295; 438/3; 204/192.12; 977/742; 977/734; 977/933

(57) ABSTRACT

A method for depositing a material on a graphene layer includes arranging a graphene layer having an exposed substantially planar surface proximate to a magnetron assembly that is operative to emit a plasma plume substantially along a first line, wherein the exposed planar surface of the graphene layer is arranged at an angle that is non-orthogonal to the first line where the first line intersects the exposed planar surface; and emitting the plasma plume from the magnetron assembly such that a layer of deposition material is disposed on the graphene layer without appreciably damaging the graphene layer.

### FIELD OF INVENTION

The present invention relates generally to thin film deposition and transistor devices, and more specifically, to thin film deposition on graphene and graphene transistor devices.

### DESCRIPTION OF RELATED ART

Graphene is a carbon monolayer material that may be used in a variety of electronic devices such as field effect transistor devices and spintronic devices. Often it may be desirable to deposit a thin layer of metallic or non-metallic material on a layer of graphene material as contact electrodes or dielectric materials to fabricate electronic devices. Efficient methods for depositing layers of materials on a layer of graphene material are desired.

### BRIEF SUMMARY

According to an embodiment of the present invention, a method for depositing a material on a graphene layer includes arranging a graphene layer having an exposed substantially planar surface proximate to a magnetron assembly that is operative to emit a plasma plume substantially along a first line, wherein the exposed planar surface of the graphene layer is arranged at an angle that is non-orthogonal to the first line where the first line intersects the exposed planar surface; and emitting the plasma plume from the magnetron assembly such that a layer of deposition material is disposed on the graphene layer without appreciably damaging the graphene layer.

According to another embodiment of the present invention, a method for fabricating a spintronic device includes depositing and patterning a graphene layer on an insulator layer, depositing a ferromagnetic insulator layer on the graphene layer, depositing an electrode layer on the ferromagnetic insulator layer; and patterning and removing portions of the electrode layer and the ferromagnetic insulator layer to define an injector portion arranged on a portion of the graphene layer, a detector portion arranged on a portion of the graphene layer and an exchange gate portion arranged on a portion of the graphene layer.

According to another embodiment of the present invention, a spintronic transistor device includes a graphene channel portion arranged on an insulator layer, an injector portion arranged on a portion of the graphene channel portion, the injector portion including a ferromagnetic insulator layer disposed on the graphene channel portion and a non-magnetic metallic electrode layer disposed on the ferromagnetic insulator layer, a detector portion arranged on a portion of the graphene channel portion, the detector portion including a ferromagnetic insulator layer disposed on the graphene channel portion and a non-magnetic metallic electrode layer disposed on the ferromagnetic insulator layer, and an exchange gate portion arranged on a portion of the graphene channel portion, the exchange gate portion including a ferromagnetic insulator layer deposited on the graphene channel portion and a gate electrode layer deposited on the ferromagnetic insulator layer.

According to another embodiment of the present invention, a spintronic transistor device includes a carbon nanotube channel portion arranged on an insulator layer, an injector portion arranged on a portion of the carbon nanotube channel portion, the injector portion including a ferromagnetic insulator layer disposed on the carbon nanotube channel portion and an electrode layer disposed on the ferromagnetic insulator layer, a detector portion arranged on a portion of the carbon nanotube channel portion, the detector portion including a ferromagnetic insulator layer disposed on the carbon nanotube channel portion and an electrode layer disposed on the ferromagnetic insulator layer, and an exchange gate portion arranged on a portion of the carbon nanotube channel portion, the exchange gate portion including a ferromagnetic insulator layer deposited on the carbon nanotube channel portion and a gate electrode layer deposited on the ferromagnetic insulator layer.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates an exemplary sputtering system.

FIG. 2 illustrates an alternate exemplary arrangement of the system of FIG. 1.

FIG. 3 illustrates an example of the resultant structure that includes a layer of deposition materials.

FIG. 4 illustrates a Raman spectra graph.

FIG. 5 illustrates another Raman spectra graph.

FIG. 6 illustrates another Raman spectra graph.

FIG. 7 illustrates a perspective view of an exemplary embodiment of a spin-transistor device.

### DETAILED DESCRIPTION

The properties of graphene materials provide considerable advantages over many materials when used in spintronic and electronic devices. Previous deposition processes such as e-beam evaporation and thermal evaporation have been used to deposit metallic and non-metallic layers of materials on graphene, however such methods have been difficult to incorporate into industrial scale production processes due to the small throughput of such processes. Other drawbacks in e-beam evaporation processes is a low-rate with high-melting point materials and difficulty in achieving precise control of stoichiometry of co-deposition of materials with very different melting points. Sputtering deposition processes generally provide high throughput and preserve film stoichiometry for material deposition. However, the energetic species in the plasma used in previous sputtering processes often caused structural damage in the graphene channel and degraded the performance of the resultant devices. The methods and systems described below provide a sputtering deposition process that facilitates high throughput deposition of metallic and non-metallic materials on a layer of graphene material without appreciably damaging the underlying graphene material. The methods described herein provide a method for fabricating an exemplary embodiment of a spintronic device.

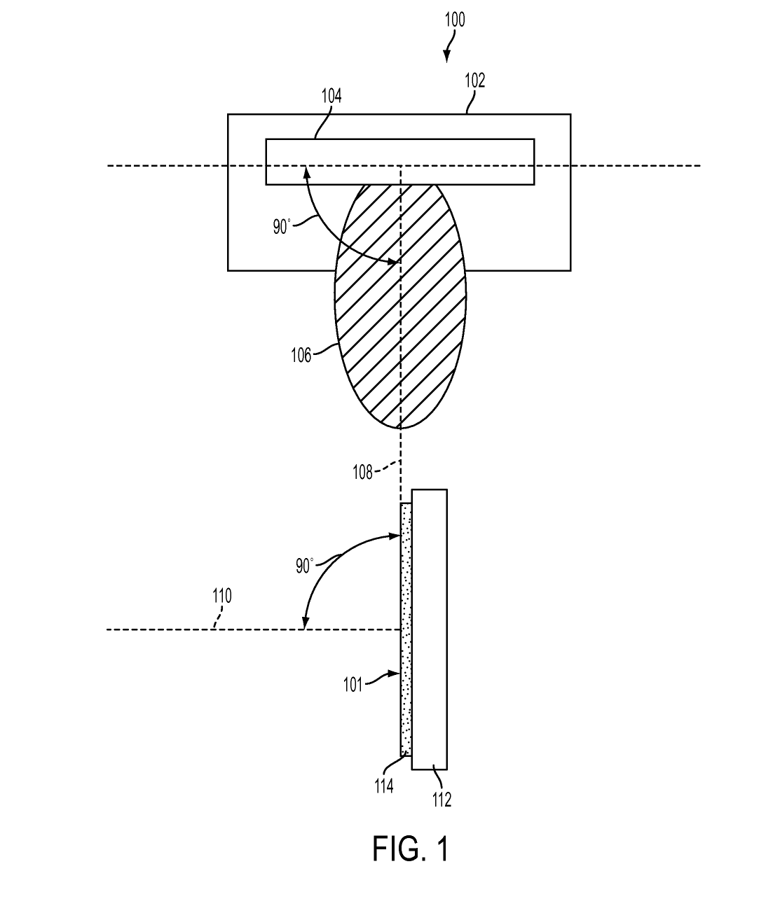

FIG. 1 illustrates an exemplary sputtering system 100 that includes a magnetron assembly 102 and a sputtering target 104 that includes a deposition material. The magnetron assembly 102 is operative to induce a plasma plume 106 that directs deposition material substantially along an axis indicated by the line 108 such that the substantial portion of the deposition material propagates along the line 108. In this regard the plasma plume 106 elongates along the direction of the electric field. A substrate 112, which may include, for example, a semiconductor or insulator material as illustrated with a graphene layer 114 disposed thereon. The graphene layer 114 may be deposited on the substrate 112 using any suitable graphene deposition process. The graphene layer 114 includes a substantially exposed planar surface 101. A line 110 is illustrated that is orthogonal to the planar surface 101. In the deposition process, the deposition material such as, for example, aluminum, titanium, platinum, gold, magnesium oxide, aluminum oxide, boron nitride, aluminum nitride, ferrites, cobalt, nickel, tantalum, tungsten, and so on, is deposited on the surface 101 of the graphene layer 114. In the illustrated embodiment, the surface 101 is arranged substantially in parallel with the line 108.

Previous methods of sputtering deposition applied in graphene device fabrication arranged (or aligned) the surface 101 orthogonal to the line 108. In the previous methods, the component of the momentum of the deposition material and the high energy particles in the plasma that is parallel to the line 108 is arranged orthogonally to the surface 101. The resultant impingement of the high energy sputtering gas species at a relatively high kinetic energy at an orthogonal angle of incidence resulted in undesirable damage to the underlying graphene layer 114.

The illustrated system and method, where the graphene layer is arranged substantially parallel to the momentum of the high energy sputtering gas species in the plasma and the sputtered deposition material along the line 108, reduces the kinetic energy that is absorbed by the graphene layer 114, when the graphene layer 114 is exposed to the sputtering plasma plume. The reduction in the kinetic energy that is absorbed by the graphene layer 114 reduces or substantially eliminates damage to the graphene layer 114 during the sputtering deposition process.

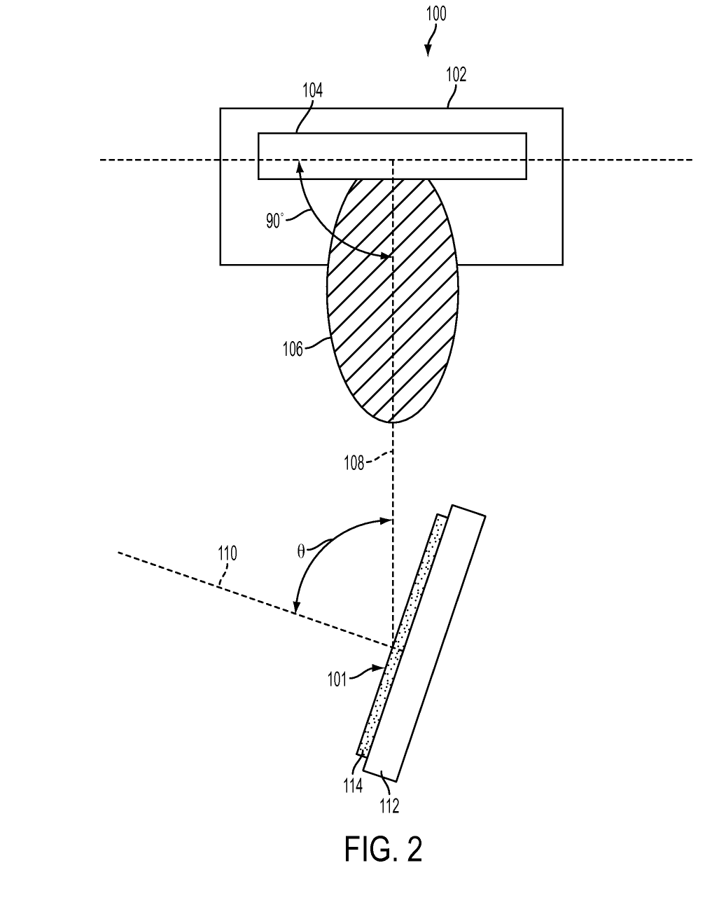

FIG. 2 illustrates an alternate exemplary arrangement of the system 100. In the illustrated alternate exemplary embodiment, the planar surface 101 of the graphene layer 114 is arranged at an oblique angle relative to the line 108 defined by the plasma plume 106. In this regard, the line 110 that is orthogonal to the substantially planar surface 101 of the graphene layer 114 defines an oblique angle (θ) relative to the line 108. The alternate exemplary embodiment illustrated in FIG. 2 provides an increased deposition rate of the deposition material on the graphene layer 114.

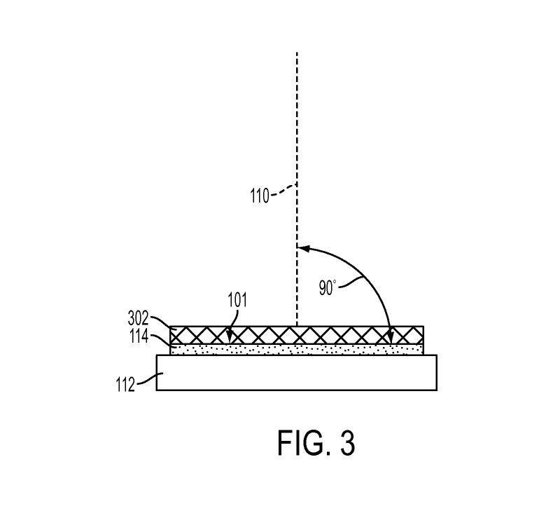

FIG. 3 illustrates an example of the resultant structure that includes a layer of deposition materials 302 arranged on, and in contact with the graphene layer 114 following a sputtering deposition process as described above in FIGS. 1 and 2.

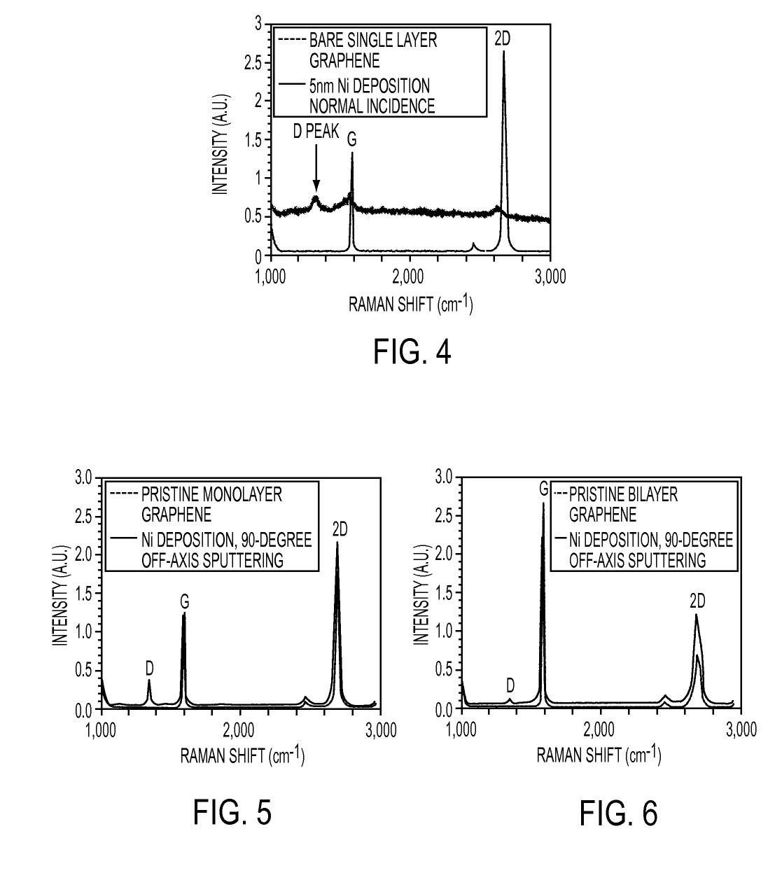

FIG. 4 illustrates a Raman spectra graph of a tested layer of graphene having a layer of Ni deposited thereon using a previous sputtering deposition process where the graphene layer was arranged orthogonal to the line 108 (of FIG. 1). In this regard, the graphene characteristic peaks G and 2D are severely reduced and distorted and the preeminent D peak is visible, which indicates extensive undesirable structural damage to the graphene layer.

FIG. 5 illustrates a Raman spectra graph of a tested layer of monolayer graphene having an approximately 1 nanometer (nm) layer of Ni and a layer of approximately 2 nm of Al deposited thereon using a sputtering deposition method similar to the method described above in FIG. 1. Compared to pristine graphene, the G and 2D peaks are largely preserved, and the D peak intensity is lower indicating less vacancies or damage in the monolayer graphene following deposition of a layer of Ni/Al on the graphene layer. In this regard, “Ni/Al” denotes a pair of layers of material such as a layer of Al disposed on a layer of Ni, or a plurality of such pairs of materials such as, for example a layer of first layer of Al disposed on a first layer of Ni, a second layer of Ni disposed on the first layer of Al, and a second layer of Al disposed on the second layer of Ni and so forth.

FIG. 6 illustrates a Raman spectra graph of a tested layer of bilayer graphene having an approximately 1 nm layer of Ni and approximately 2 nm layer of Al deposited thereon using a sputtering deposition method similar to the method described above in FIG. 1. Compared to pristine graphene, the G and 2D peaks are largely preserved and the D peak intensity is considerably lower indicating less vacancies or damage in the bilayer graphene following deposition of a layer of Ni/Al on the graphene layer.

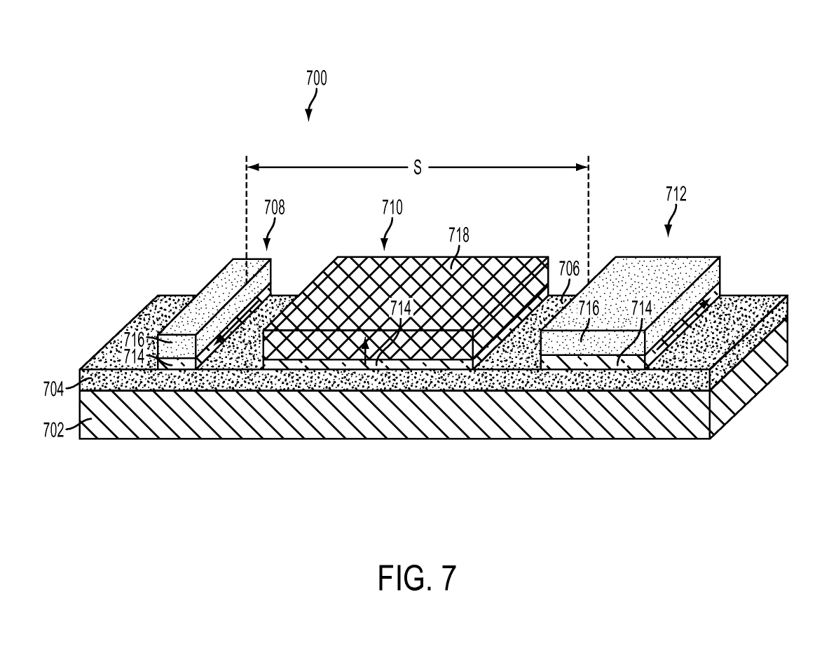

FIG. 7 illustrates a perspective view of an exemplary embodiment of a spin-transistor device 700 that may be fabricated using similar exemplary deposition methods as described above in FIGS. 1 and 2. In this regard, referring to FIG. 7, the device 700 is arranged on an insulator layer 704 that may include, for example an oxide material such as SiO₂ and hexagonal boron nitride (h-BN). The insulator layer 704 is arranged on a conductive substrate 702 that may include, for example, a highly-doped semiconductor material such as silicon or a germanium material. A carbon channel layer 706 is transferred on the insulator layer 704 using a suitable carbon deposition process. In this regard, the carbon channel layer 706 may include, for example, a layer of graphene material or carbon nanotubes. The device 700 includes a spin injector (source) portion 708, a spin detector (drain) portion 712, and an exchange gate portion 710. The injector portion 708, the detector portion 712, and the exchange gate portion 710 each include an ultrathin ferromagnetic insulator (FI) layer 714 having a thickness less than approximately 5 nm that is directly in contact with the carbon channel layer 706. The FI layer 714 may include, for example, an insulating ferrite material such as CoFe₂O₄, NiFe₂O₄, MnFe₂O₄, or ZnFe₂O₄, diluted magnetic semiconductors such as TiO2:Co or GaMnAs and so on, . The FI layer 714 may be deposited by, for example, a sputtering deposition process similar to the processes described above in FIGS. 1 and 2. A non-magnetic or magnetic electrode layer 716 of conductive material such as, for example, Ti, Al, Au, Pt Co, Fe, Ni, CoFeB and so on is disposed on the FI layer 714. In an alternate exemplary embodiment electrode layer 716 may include, for example a plurality of layers of magnetic materials such as, for example, Co/Pt, Co/Pt, Co/Pd, or Co/Ni, or non-magnetic materials. The electrode layer may have a thickness of between approximately 20 nm to 200. In fabrication, following the deposition of the FI layer 714, and the electrode layer 716, a lithographic patterning and etching process may be performed to define the injector portion 708, the detector portion 712, and the exchange gate portion 710.

The FI layers 714 of the injector portion 708 and the detector portion 712 have spin-dependent barrier heights and may generate spin-polarized currents in the carbon channel layer 706 even when injecting from the non-magnetic electrode layers 716 due to a spin dependent tunneling probability. This affect results in an expected exponential dependence of the spin polarization with the thickness of the FI layer 714, and thus large spin polarizations are accessible with a small spin-splitting in the FI layer 714.

In operation, when the injector portion 708 and the detector portion 712 are arranged on the carbon channel 706 so that the spacing (s) distance between the injector portion 708 and the detector portion 712 is within the spin diffusion length of the carbon layer, a large resistance state will arise in the antiparallel spin configuration of the injector portion 708 and the detector portion 712, and a smaller resistance state in the parallel configuration thereby defining both an ON state and an OFF state. The spin diffusion length is the length scale over which the spin polarization of conducting electrons loses coherence. The magnitude of the spin diffusion length in the carbon channel layer 706 depends on a number of factors, including the substrate materials, the amount of impurities and/or defects in the channel, the mobility, and the temperature. It can range from a few nanometers to a few microns. Therefore, the spacing between the injector 708 and the detector 712 may also be in the range of submicron to a few microns. In order to realize a change in the resistance state of the device 700 the spin direction of the carriers in the carbon channel 706 is rotated by electrical means. This may be done by the means of the exchange gate portion 710 arranged on the carbon channel 706 between the injector portion 708 and the detector portion 712. At the interface between the FI layers 714 and the carbon channel 716, a Heisenberg exchange field is present; the direction of the exchange field is controlled by the magnetization of the FI layers 714. The exchange field will induce a torque on the spin of the carriers drifting in the channel between the injector portion 708 and the detector portion 712 only if the exchange field and the angular momentum of the carriers are non-collinear. A spin precession in the channel can therefore be induced depending on the direction of the magnetization of the exchange gate portion 710 with respect to the magnetization direction of the injector portion 708 and the detector portion 712 contacts. In the case of a parallel or antiparallel alignment, no precession is expected, non-collinear alignments result in a spin precession and hence a depolarization of the overall spin current in the channel due to the presence of scattering events.

The magnetization direction of the exchange gate portion 710 may be controlled by using an electrode 718 with a substantial contribution to the interfacial anisotropy (e.g., metals with high Z and high spin orbit coupling such as Au and Pt, or magnetic multilayer stacks, such as Co/Pt, Co/Pd, Co/Ni, to induce perpendicular magnetic anisotropy via the presence of high spin orbit at Co/Pt interfaces). The carrier concentration at the FI-electrode metal interface in the exchange gate portion 710 may be modulated by the presence of an electric field which results in a variation of the magnetic contribution of the anisotropy of the interface and a rotation of the magnetization of the FI layer 714 in the exchange gate portion 710.

The technical effects and benefits of the embodiments described herein provide a method for sputtering deposition of a material on a carbon layer, and a spin-transistor device that may be fabricated using the sputtering deposition methods described herein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A method for depositing a material on a graphene layer, the method comprising:
arranging a graphene layer having an exposed substantially planar surface proximate to a magnetron assembly that is operative to emit a plasma plume substantially along a first line, wherein the exposed planar surface of the graphene layer is arranged at an angle that is non-orthogonal to the first line where the first line intersects the exposed planar surface; and emitting the plasma plume from the magnetron assembly such that a layer of deposition material is disposed on the graphene layer without appreciably damaging the graphene layer.

2. The method of claim 1, wherein the exposed planar surface of the graphene layer is arranged at an angle that is substantially parallel to the first line.

3. The method of claim 1, wherein the exposed planar surface of the graphene layer is arranged at an angle that is oblique to the first line where the first line intersects the exposed planar surface.

4. A method for fabricating a spintronic device, the method comprising:
depositing and patterning a graphene layer on an insulator layer;
depositing a ferromagnetic insulator layer on the graphene layer;
depositing an electrode layer on the ferromagnetic insulator layer; and patterning and removing portions of the electrode layer and the ferromagnetic insulator layer to define an injector portion arranged on a portion of the graphene layer, a detector portion arranged on a portion of the graphene layer and an exchange gate portion arranged on a portion of the graphene layer.

5. The method of claim 4, wherein the exchange gate portion is arranged between the injector portion and the detector portion.

6. The method of claim 4, wherein the ferromagnetic insulator layer has a thickness of less than 10 nm.

7. The method of claim 4, wherein the ferromagnetic insulator layer is deposited with a sputtering deposition process.

8. The method of claim 7, wherein the sputtering process includes:
arranging the graphene layer having an exposed substantially planar surface proximate to a magnetron assembly that is operative to emit a plasma plume substantially along a first line, wherein the exposed planar surface of the graphene layer is arranged at an angle that is non-orthogonal to the first line where the first line intersects the exposed planar surface; and
emitting the plasma plume from the magnetron assembly such that the ferromagnetic insulator layer is deposited on the graphene layer without appreciably damaging the graphene layer.

9. The method of claim 8, wherein the exposed planar surface of the graphene layer is arranged at an angle that is substantially parallel to the first line.

10. The method of claim 8, wherein the exposed planar surface of the graphene layer is arranged at an angle that is oblique to the first line where the first line intersects the exposed planar surface.

11. The method of claim 4, wherein the ferromagnetic insulator layer includes an insulating ferrite material that is selected from the group consisting of CoFe₂O₄, NiFe₂O₄, MnFe₂O₄, or ZnFe₂O₄.

12. The method of claim 4, wherein the ferromagnetic insulator layer includes an insulating europium chalcogenide material that is selected from the group consisting of EuS and EuO, or includes a diluted magnetic semiconductor material that is selected from the group consisting of TiO2:Co and GaMnAs.

13. The method of claim 4, wherein the electrode layer includes a layer of non-magnetic metallic material.

14. The method of claim 4, wherein the non-magnetic metallic layer is selected from the group consisting of Au, Pt, Ti, Al, and Pd.

15. The method of claim 4, wherein the electrode layer includes magnetic multilayer stack of materials.

16. The method of claim 15, wherein the magnetic metallic multilayer stack is selected from the group consisting of Co/Pt, Co/Pd, and Co/Ni.

17.-25. (canceled)
